(19) United States
(12) Patent Application Publication
(10) Pub. No.: US 2026/0362899 A1
(43) Pub. Date: Nov. 12, 2026

(54) DISPLAY DEVICE

(71) Applicant: Sharp Display Technology Corporation, Kameyama, City, Mie (JP)

(72) Inventors: Tadayoshi MIYAMOTO, Kameyama City (JP); Yoshinobu NAKAMURA, Kameyama City (JP); Sohtaroh TANAKA, Kameyama City (JP)

(21) Appl. No.: 19/487,090

(22) PCT Filed: May 29, 2023
(86) PCT No.: PCT/JP2023/019901

§ 371 Date: Nov. 24, 2025

(51) Int. Cl. H10K 59/121; H10K 59/80

(52) U.S. Cl. CPC H10K 59/1213; H10K 59/873

(57) ABSTRACT

A display device includes: a base substrate; and a thin-film transistor layer provided on the base substrate, the thin-film transistor layer including a plurality of first thin-film transistors arranged for each of a plurality of subpixels, and including a plurality of second thin-film transistors arranged as peripheral circuits in a frame region, each of the plurality of first thin-film transistors and each of the plurality of second thin-film transistors including a first semiconductor layer and a second semiconductor layer, respectively, both formed from an oxide semiconductor, the thin-film transistor layer including, in at least one of the plurality of first thin-film transistors, a conductive layer provided adjacently to the base substrate with respect to the first semiconductor layer. A protective pattern formed in a same layer and containing a same material as the conductive layer is provided around the second semiconductor layer in a plan view.

### TECHNICAL FIELD

The disclosure relates to a display device.

### BACKGROUND ART

Attention has been recently drawn to self-emission organic EL display devices incorporating organic electroluminescence (hereinafter, also referred to as EL) elements, as display devices alternative to liquid crystal displays. Such an organic EL display device has a plurality of thin-film transistors (hereinafter, also referred to as “TFTs”) provided for each subpixel, which is the minimum unit of an image. Here, well-known examples of a semiconductor layer constituting TFTs include, but not limited to, a semiconductor layer made of high-mobility polysilicon, and a semiconductor layer made of an oxide semiconductor having a small leakage current, such as an In—Ga—Zn—O semiconductor.

For instance, Patent Literature 1 discloses a display device including a pixel unit and a driving circuit unit each having transistors in which channels are formed in an oxide semiconductor layer formed from an oxide semiconductor.

### CITATION LIST

### Patent Literature

Patent Literature 1: Japanese Patent No. 6219562

### SUMMARY

### Technical Problem

By the way, in an organic EL display device in which TFTs formed from an oxide semiconductor are provided in each subpixel, it has been proposed to provide a TFT formed from an oxide semiconductor also as a part of a peripheral circuit, such as a gate driver. Unfortunately, an oxide semiconductor TFT is more susceptible to TFT-property degradation especially in the peripheral circuit, across which a high voltage is applied, than a polysilicon semiconductor TFT due to, for instance, an insulating film's breakdown caused by discharge of static electricity accumulated during the manufacturing process steps, moisture intrusion from, but not limited to, an organic resin material, and other factors; hence, there is room for improvement in such an oxide semiconductor TFT.

The disclosure has been made in view of this problem, and it is an object of the disclosure to prevent property degradation of TFTs constituting a peripheral circuit of a display device provided with the TFTs formed from an oxide semiconductor.

### Solution to Problem

To achieve the above object, a display device according to the disclosure includes the following: a base substrate; and a thin-film transistor layer provided on the base substrate. The thin-film transistor layer includes a plurality of first thin-film transistors arranged for each of a plurality of subpixels constituting a display region, and includes a plurality of second thin-film transistors arranged as peripheral circuits in a frame region around the display region. Each of the plurality of first thin-film transistors and each of the plurality of second thin-film transistors includes a first semiconductor layer and a second semiconductor layer, respectively, both formed from an oxide semiconductor. The thin-film transistor layer includes, in at least one of the plurality of first thin-film transistors, a conductive layer provided adjacently to the base substrate with respect to the first semiconductor layer. A protective pattern formed in the same layer and containing the same material as the conductive layer is provided around the second semiconductor layer in a plan view.

### Advantageous Effects of Disclosure

The disclosure can prevent property degradation of TFTs constituting a peripheral circuit of a display device provided with the TFTs formed from an oxide semiconductor.

### BRIEF DESCRIPTION OF DRAWINGS

FIG. 1 is a plan view of the schematic configuration of an organic EL display device according to a first embodiment of the disclosure.

FIG. 2 is a plan view of a display region of the organic EL display device according to the first embodiment of the disclosure.

FIG. 3 is a cross-sectional view of the display region of the organic EL display device according to the first embodiment of the disclosure.

FIG. 4 is an equivalent circuit diagram of a TFT layer constituting the organic EL display device according to the first embodiment of the disclosure.

FIG. 5 is a cross-sectional view of an organic EL layer constituting the organic EL display device according to the first embodiment of the disclosure.

FIG. 6 is a plan view of a second TFT constituting the organic EL display device according to the first embodiment of the disclosure.

FIG. 7 is a cross-sectional view of a frame region of the organic EL display device taken along line VII-VII in FIG. 6.

FIG. 8 is a plan view of a first modification of the second TFT constituting the organic EL display device according to the first embodiment of the disclosure, and corresponds to FIG. 6.

FIG. 9 is a plan view of a second modification of the second TFT constituting the organic EL display device according to the first embodiment of the disclosure, and corresponds to FIG. 9.

FIG. 10 is a plan view of a third modification of the second TFT constituting the organic EL display device according to the first embodiment of the disclosure, and corresponds to FIG. 6.

FIG. 11 is a plan view of a fourth modification of the second TFT constituting the organic EL display device according to the first embodiment of the disclosure, and corresponds to FIG. 6.

### DESCRIPTION OF EMBODIMENTS

The embodiments of the disclosure will be detailed on the basis of the drawings. It is noted that the disclosure is not limited to the following embodiments.

### First Embodiment

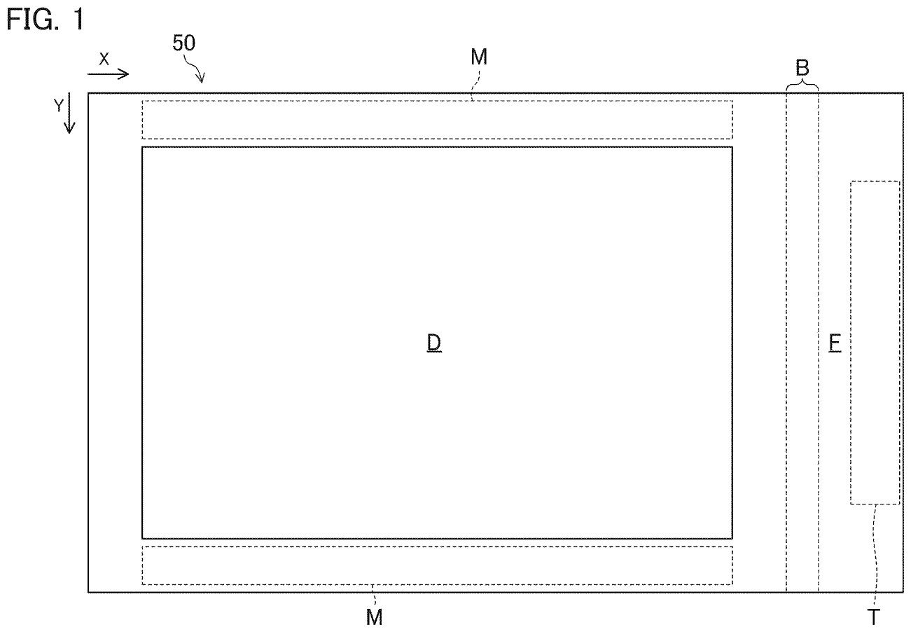

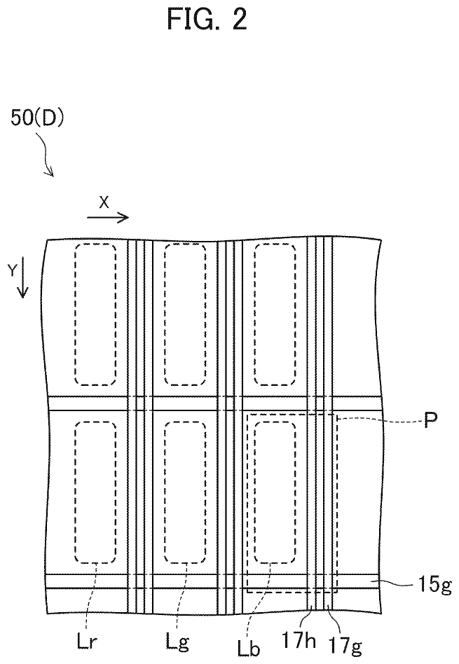

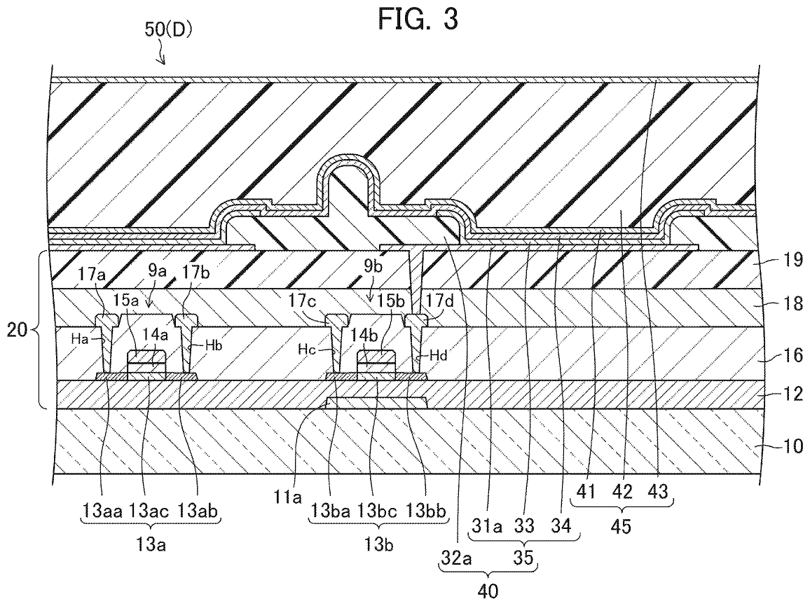

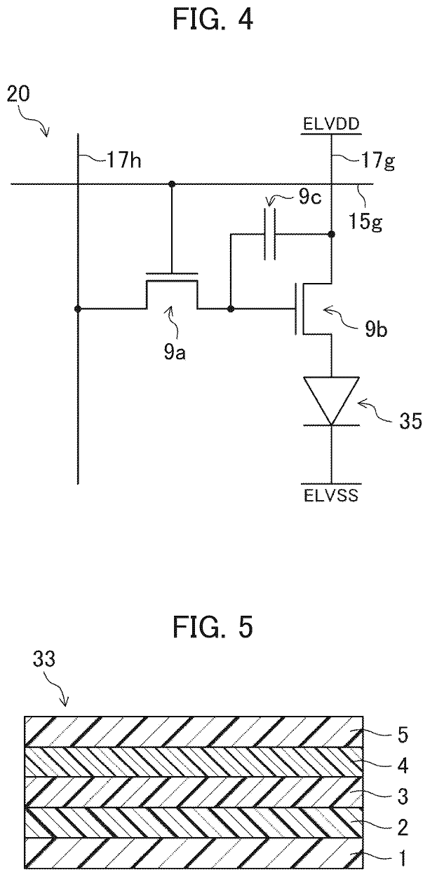

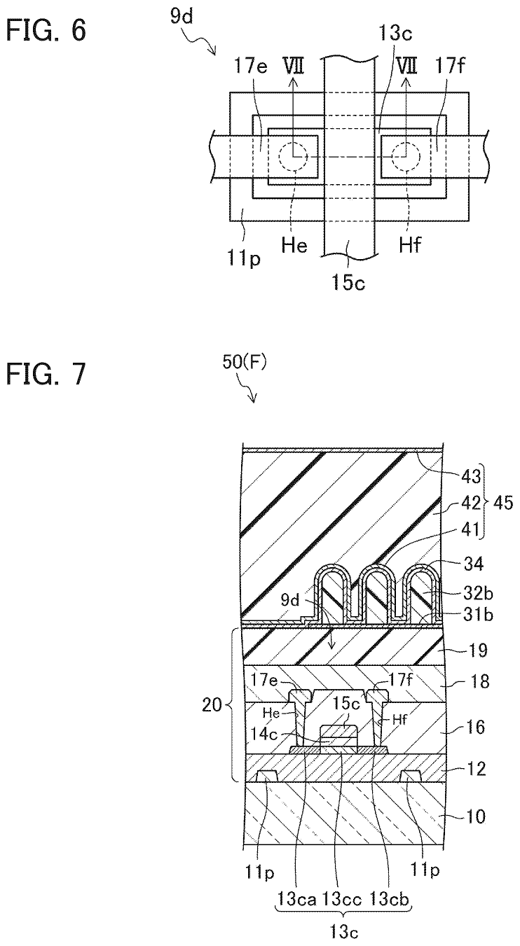

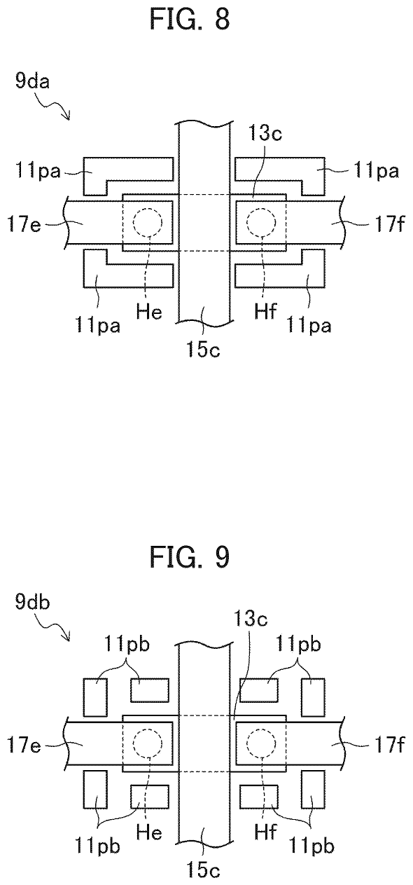

FIGS. 1 to 11 illustrate a first embodiment of a display device according to the disclosure. It is noted that each embodiment below will describe, by way of example, an organic EL display device including an organic EL element layer as a display device including a light-emitting element layer. Here, FIG. 1 is a plan view of the schematic configuration of an organic EL display device 50 according to this embodiment. In addition, FIGS. 2 and 3 are a plan view and a cross-sectional view of a display region D of the organic EL display device 50. In addition, FIG. 4 is an equivalent circuit diagram of a TFT layer 20 constituting the organic EL display device 50. In addition, FIG. 5 is a cross-sectional view of an organic EL layer 35 constituting the organic EL display device 50. In addition, FIG. 6 is a plan view of a peripheral TFT 9d provided as a second TFT constituting the organic EL display device 50. In addition, FIG. 7 is a cross-sectional view of a frame region F of the organic EL display device 50 taken along line VII-VII in FIG. 6. In addition, FIGS. 8, 9, 10, and 11 are plan views of a peripheral TFT 9da, a peripheral TFT 9db, a peripheral TFT 9dc, and a peripheral TFT 9dd as first, second, third, and fourth modifications of the peripheral TFT 9d, respectively, and these drawings correspond to FIG. 6.

As illustrated in FIG. 1, the organic EL display device 50 includes, for instance, the display region D provided rectangularly and provided for image display, and the frame region F provided in the form of a frame around the display region D. It is noted that although this embodiment describes the display region D having a rectangular shape by way of example, this rectangular shape includes substantially rectangular shapes, such as a shape with an arc-shaped side, a shape with an arc-shaped corner, and a shape with part of a side being notched.

The display region D includes a plurality of subpixels P arranged in matrix, as illustrated in FIG. 2. Further, as illustrated in FIG. 2, a subpixel P having a red emission region Lr for red display, a subpixel P having a green emission region Lg for green display, and a subpixel P having a blue emission region Lb for blue display, for instance, are provided in the display region D so as to be adjacent to one another. It is noted that the display region D is structured for instance such that three adjacent subpixels P having the red emission region Lr, green emission region Lg, and blue emission region Lb constitute a single pixel.

The frame region F includes a terminal section T provided at the right end in FIG. 1 so as to extend in one direction (the Y-direction of the drawing). In addition, between the display region D and terminal section T is, as illustrated in FIG. 1, that is, in the frame region F closer to the display region D than the terminal section T is a bending section B provided so as to extend in one direction (the Y-direction of the drawing); here, the bending section B is, for instance, 180° (U-shape) bendable about a bending axis, which extends in the Y-direction of the drawing. The frame region F also includes gate driving circuits M provided as peripheral circuits at its upper and lower ends in FIG. 1.

The organic EL display device 50 includes the following as illustrated in FIG. 3: a glass substrate 10 provided as a base substrate; the TFT layer 20 provided on the glass substrate 10; an organic EL element layer 40 provided as a light-emitting element layer on the TFT layer 20; and a sealing film 45 provided on the organic EL element layer 40. It is noted that although this embodiment describes the glass substrate 10 as a base substrate by way of example, the base substrate may be, for instance, a resin substrate formed from an organic resin material, such as polyimide resin.

The TFT layer 20 includes the following as illustrated in FIGS. 3 and 7: a base coat film 12 provided on the glass substrate 10; a plurality of selection TFTs 9a, a plurality of drive TFTs 9b, a plurality of capacitors 9c (see FIG. 4), and a plurality of peripheral TFTs 9d all provided on the base coat film 12; and an insulating protective film 18 and a flattening film 19 provided sequentially on the individual selection TFTs 9a, individual drive TFTs 9b, individual capacitors 9c, and individual peripheral TFTs 9d. Here, the TFT layer 20 includes, as illustrated in FIG. 2, a plurality of gate lines 15g provided so as to extend in parallel with each other in the X-direction of the drawing. The TFT layer 20 also includes, as illustrated in FIG. 2, a plurality of source lines 17h provided so as to extend in parallel with each other in a direction crossing (orthogonal to) the plurality of gate lines 15g, that is, in the Y-direction of the drawing. The TFT layer 20 also includes, as illustrated in FIG. 2, a plurality of power supply lines 17g provided so as to extend in parallel with each other in the Y-direction of the drawing. Moreover, each of the power supply lines 17g is provided so as to be adjacent to a corresponding one of the source lines 17h, as illustrated in FIG. 2. Further, the TFT layer 20 is structured, as illustrated in FIG. 4, such that each subpixel P is provided with a single selection TFT 9a, a single drive TFT 9b, and a single capacitor 9c. It is noted that in the TFT layer 20, the selection TFT 9a and drive TFT 9b in each subpixel P of the display region D are provided as first TFTs, and the peripheral TFTs 9d in the frame region F are provided as second TFTs. The TFT layer 20 also includes the following sequentially stacked on the glass substrate 10, as illustrated in FIGS. 3 and 7: a first metal film constituting, but not limited to, a conductive layer 11a, which will be described later on; the base coat film 12 provided as a first inorganic insulating film; a semiconductor film constituting, but not limited to, a first semiconductor layer 13a, a first semiconductor layer 13b, and a second semiconductor layer 13c, all of which will be described later on; a second metal film constituting, but not limited to, gate insulating films 14a, 14b, and 14c and the gate lines 15g all provided as a second inorganic insulating film; an interlayer insulating film 16 provided as a third inorganic insulating film; a third metal film constituting the source lines 17h, power supply lines 17g, and other components; the insulating protective film 18 provided as a fourth inorganic insulating film; and the flattening film 19.

The base coat film 12, the gate insulating films 14a, 14b and 14c, the interlayer insulating film 16, and the insulating protective film 18 are each formed from an inorganic insulating monolayer film or inorganic insulating multilayer film of, but not limited to, silicon nitride, silicon oxide, silicon oxynitride. Here, the surfaces of the base coat film 12 and gate insulating films 14a, 14b and 14c adjacent to the first semiconductor layer 13a, the first semiconductor layer 13b, and the second semiconductor layer 13c are each formed from a silicon oxide film.

The selection TFT 9a in each subpixel P is electrically connected to the corresponding gate line 15g and source line 17h, as illustrated in FIG. 4. Further, the selection TFT 9a includes the following as illustrated in FIG. 3: the first semiconductor layer 13a provided on the base coat film 12; a first gate electrode 15a provided on the first semiconductor layer 13a with the gate insulating film 14a interposed therebetween; and a first source electrode 17a and a first drain electrode 17d provided on the interlayer insulating film 16 so as to be spaced from each other.

The first semiconductor layer 13a is formed from the foregoing semiconductor film containing an oxide semiconductor, such as In—Ga—Zn—O, and this layer includes, as illustrated in FIG. 3, a first source region 13aa and a first drain region 13ab defined so as to be spaced from each other, and a first channel region 13ac defined between the first source region 13aa and the first drain region 13ab. Here, an In—Ga—Zn—O semiconductor is a ternary oxide of indium (In), gallium (Ga), and zinc (Zn) and contains In, Ga, and Zn at a non-limiting ratio (composition ratio). Further, this In—Ga—Zn—O oxide semiconductor may be amorphous or crystalline. It is noted that a preferable crystalline In—Ga—Zn—O oxide semiconductor is a crystalline In—Ga—Zn—O oxide semiconductor whose c-axis is nearly perpendicular to a layer surface. It is also noted that other kinds of oxide semiconductors may be contained instead of an In—Ga—Zn—O oxide semiconductor. An example of the other kinds of oxide semiconductors that may be contained is an In—Sn—Zn—O semiconductor (e.g., In₂O₃—SnO₂—ZnO, InSnZnO). Here, an In—Sn—Zn—O semiconductor is a ternary oxide of indium (In), tin (Sn), and zinc (Zn). Further, other examples of the other kinds of oxide semiconductors that may be contained include, but not limited to, an In—Al—Zn—O semiconductor, an In—Al—Sn—Zn—O semiconductor, a Zn—O semiconductor, an In—Zn—O semiconductor, a Zn—Ti—O semiconductor, a Cd—Ge—O semiconductor, a Cd—Pb—O semiconductor, cadmium oxide (CdO), a Mg—Zn—O semiconductor, an In—Ga—Sn—O semiconductor, an In—Ga—O semiconductor, a Zr—In—Zn—O semiconductor, a Hf—In—Zn—O semiconductor, an Al—Ga—Zn—O semiconductor, a Ga—Zn—O semiconductor, an In—Ga—Zn—Sn—O semiconductor, InGaO₃(ZnO)₅, magnesium zinc oxide (MgₓZn₁₋ₓO), and cadmium zinc oxide (CdₓZn₁₋ₓO). It is noted that a usable Zn—O semiconductor is an amorphous semiconductor of ZnO with one or more kinds of impurity elements selected from, but not limited to, a Group I element, a Group XIII element, a Group XIV element, a Group XV element, and a Group XVII element being added thereto, a polycrystalline semiconductor of such ZnO, or a crystallite semiconductor of such ZnO including amorphous and polycrystalline substances; alternatively, a usable Zn—O semiconductor is a Zn—O semiconductor without any impurity elements being added thereto.

The first gate electrode 15a is provided so as to overlap the first channel region 13ac of the first semiconductor layer 13a, as illustrated in FIG. 3, and is configured to control the electrical continuity between the first source region 13aa and first drain region 13ab of the first semiconductor layer 13a. Here, the first gate electrode 15a is formed from the second metal film, like the gate lines 15g.

The first source electrode 17a and the first drain electrode 17b are, as illustrated in FIG. 3, electrically connected to the first source region 13aa and first drain region 13ab of the first semiconductor layer 13a, respectively, via a first contact hole Ha and a second contact hole Hb both formed in the interlayer insulating film 16. Here, the first source electrode 17a and the first drain electrode 17b are formed from the third metal film, like the source lines 17h and the power supply lines 17g.

The drive TFT 9b in each subpixel P is electrically connected to the corresponding selection TFT 9a and power supply line 17g, as illustrated in FIG. 4. Further, the drive TFT 9b includes the following as illustrated in FIG. 3: the conductive layer 11a provided on the glass substrate 10; the first semiconductor layer 13b provided on the base coat film 12; a first gate electrode 15b provided on the first semiconductor layer 13b with the gate insulating film 14b interposed therebetween; and a first source electrode 17c and a first drain electrode 17d provided on the interlayer insulating film 16 so as to be spaced from each other.

The conductive layer 11a is provided so as to overlap the first semiconductor layer 13b, as illustrated in FIG. 3. Here, the conductive layer 11a is formed from the first metal film. It is noted that the conductive layer 11a may have a light blocking capability.

The first semiconductor layer 13b is formed from the foregoing semiconductor film containing an oxide semiconductor, such as In—Ga—Zn—O, like the first semiconductor layer 13a, and as illustrated in FIG. 3, the first semiconductor layer 13b includes a first source region 13ba and a first drain region 13bb defined so as to be spaced from each other, and a first channel region 13bc defined between the first source region 13ba and the first drain region 13bb.

The first gate electrode 15b is provided so as to overlap the first channel region 13bc of the first semiconductor layer 13b, as illustrated in FIG. 3, and is configured to control the electrical continuity between the first source region 13ba and first drain region 13bb of the first semiconductor layer 13b. Here, the first gate electrode 15b is formed from the second metal film, like the gate lines 15g.

The first source electrode 17c and the first drain electrode 17d are, as illustrated in FIG. 3, electrically connected to the first source region 13ba and first drain region 13bb of the first semiconductor layer 13b, respectively, via a third contact hole Hc and a fourth contact hole Hd both formed in the interlayer insulating film 16. Here, the first source electrode 17c and the first drain electrode 17d are formed from the third metal film, like the source lines 17h and the power supply lines 17g. Moreover, as illustrated in FIG. 3, the first drain electrode 17d of the drive TFT 9b is electrically connected to a first electrode 31a, which will be described later on, via a contact hole formed in the insulating protective film 18 and flattening film 19.

The capacitor 9c in each subpixel P is electrically connected to the corresponding selection TFT 9a and power supply line 17g, as illustrated in FIG. 4. Here, the capacitor 9c includes, for example, a lower conductive layer formed from the second metal film, an upper conductive layer formed from the third metal film, and the interlayer insulating film 16 provided between these lower conductive layer and upper conductive layer. It is noted that the upper conductive layer is electrically connected to the power supply lines 17g.

The peripheral TFTs 9d constitute the gate driving circuits M and each include the following as illustrated in FIG. 7: a protective pattern 11p provided on the glass substrate 10; the second semiconductor layer 13c provided on the base coat film 12; a second gate electrode 15c provided on the second semiconductor layer 13c with the gate insulating film 14c interposed therebetween; and a second source electrode 17e and a second drain electrode 17f provided on the interlayer insulating film 16 so as to be spaced from each other.

The protective pattern 11p is formed from the first metal film, like the conductive layer 11a, and as illustrated in FIG. 6, the protective pattern 11p is provided annularly in the form of a rectangular frame so as to surround the second semiconductor layer 13c in plan view.

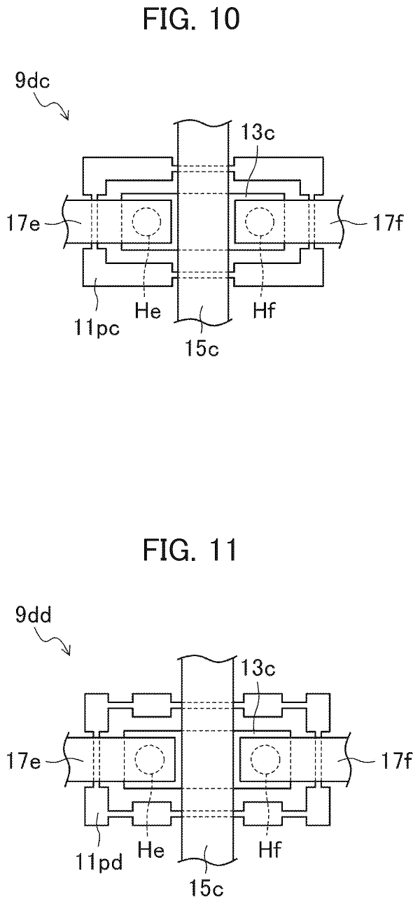

It is noted that although this embodiment describes, by way of example, the peripheral TFTs 9d including the protective pattern 11p provided in a ring shape with the same line width, the peripheral TFTs 9d may be each any of the following peripheral TFTs: a peripheral TFT 9da including a protective pattern 11pa illustrated in FIG. 8; a peripheral TFT 9db including a protective pattern 11pb illustrated in FIG. 9; a peripheral TFT 9dc including a protective pattern 11pc illustrated in FIG. 10; and a peripheral TFT 9dd including a protective pattern 11pd illustrated in FIG. 11.

To be specific, the peripheral TFT 9da includes, as illustrated in FIG. 8, four protective patterns 11pa provided in the form of islands so as to surround the second semiconductor layer 13c in plan view, and not to overlap, in plan view, wiring lines coupling to the respective second gate electrode 15c, second source electrode 17e, and second drain electrode 17f.

Further, the peripheral TFT 9db includes, as illustrated in FIG. 9, eight protective patterns 11pb provided in the form of islands so as to surround the second semiconductor layer 13c in plan view, and not to overlap, in plan view, wiring lines coupling to the respective second gate electrode 15c, second source electrode 17e, and second drain electrode 17f.

Further, the peripheral TFT 9dc includes, as illustrated in FIG. 10, a protective pattern 11pc provided annularly so as to surround the second semiconductor layer 13c in plan view, and provided such that in plan view, a portion overlapping wiring lines coupling to the respective second gate electrode 15c, second source electrode 17e, and second drain electrode 17f is narrower than a portion not overlapping the wiring lines. That is, the protective pattern 11pc is composed of the four protective patterns 11pa (see FIG. 8) coupled together.

Further, the peripheral TFT 9dd includes, as illustrated in FIG. 11, a protective pattern 11pd provided annularly so as to surround the second semiconductor layer 13c in plan view, and provided such that in plan view, a portion overlapping wiring lines coupling to the respective second gate electrode 15c, second source electrode 17e, and second drain electrode 17f is narrower than a portion not overlapping the wiring lines. That is, the protective pattern 11pd is composed of the eight protective patterns 11pb (see FIG. 9) coupled together.

The second semiconductor layer 13c is formed from the foregoing semiconductor film containing an oxide semiconductor, such as In—Ga—Zn—O, like the first semiconductor layers 13a and 13b, and as illustrated in FIG. 7, the second semiconductor layer 13c includes a second source region 13ca and a second drain region 13cb defined so as to be spaced from each other, and a second channel region 13cc defined between the second source region 13ca and the second drain region 13cb.

The second gate electrode 15c is provided so as to overlap the second channel region 13cc of the second semiconductor layer 13c, as illustrated in FIG. 7, and is configured to control the electrical continuity between the second source region 13ca and second drain region 13cb of the second semiconductor layer 13c. Here, the second gate electrode 15c is formed from the second metal film, like the gate lines 15g.

The second source electrode 17e and the second drain electrode 17f are, as illustrated in FIG. 7, electrically connected to the second source region 13ca and second drain region 13cb of the second semiconductor layer 13c, respectively, via a fifth contact hole He and a sixth contact hole Hf both formed in the interlayer insulating film 16. Here, the second source electrode 17e and the second drain electrode 17f are formed from the third metal film, like the source lines 17h and the power supply lines 17g.

The flattening film 19 has a flat surface in the display region D and is formed from, but not limited to, an organic resin material, such as polyimide resin.

As illustrated in FIG. 3, the organic EL element layer 40 includes a plurality of organic EL elements 35 provided as a plurality of light-emitting elements arranged on the TFT layer 20 in matrix in correspondence with the plurality of subpixels P. Here, the organic EL elements 35 each include the following as illustrated in FIG. 3: the first electrode 31a provided on the TFT layer 20; an organic EL layer 33 provided on the first electrode 31a; and a second electrode 34 provided on the organic EL layer 33 so as to be shared in the entire display region D.

As illustrated in FIG. 3, the first electrode 31a is electrically connected to the first drain electrode 17d of the drive TFT 9b in each subpixel P via a contact hole formed in the insulating protective film 18 and flattening film 19. Further, the first electrode 31a has the function of injecting holes (positive holes) into the organic EL layers 33. Further, the first electrode 31a is more desirably formed using a material having a large work function, in order to improve the efficiency of hole injection into the organic EL layers 33. Here, the first electrode 31a is made of metal, such as, but not limited to, silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Further, the first electrode 31a may be made of, but not limited to, alloy of astatine (At) and astatine oxide (AtO₂). Furthermore, the first electrode 31a may be made of conductive oxide, such as, but not limited to, tin oxide (SnO), zinc oxide (ZnO), indium tin oxide (ITO), and indium zinc oxide (IZO). Further, the first electrode 31 a may be formed by stacking multiple layers made of the above materials. It is noted that examples of a compound material having a large work function include indium tin oxide (ITO) and indium zinc oxide (IZO). Furthermore, the first electrode 31a has a perimeter covered with an edge cover 32a provided all over the display region D in a lattice shape. The edge cover 32a is formed from an organic resin, such as, but not limited to, polyimide resin and acrylic resin, or a polysiloxane spin-on-glass (SOG) material. It is noted that as illustrated in FIG. 3, a part of the surface of the edge cover 32a protrudes upward in the drawing to constitute pixel photo-spacers provided in the form of islands.

As illustrated in FIG. 5, the organic EL layer 33 includes a hole injection layer 1, a hole transport layer 2, an emission layer 3, an electron transport layer 4, and an electron injection layer 5 sequentially stacked on the first electrode 31a.

The hole injection layer 1 is also called an anode buffer layer and has the function of bringing the energy levels of the first electrode 31a and organic EL layer 33 close to each other to improve the efficiency of hole injection from the first electrode 31a into the organic EL layer 33. Here, examples of the material of the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has the function of improving the efficiency of hole transport from the first electrode 31a to the organic EL layer 33. Here, examples of the material of the hole transport layer 2 include a porphyrin derivative, an aromatic tertiary amine compound, a styrylamine derivative, polyvinylcarbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, and zinc selenide.

The emission layer 3 is a region where holes and electrons are respectively injected from the first electrode 31a and second electrode 34 applied with voltage, and where the holes and electrons recombine together. Here, the emission layer 3 is formed from a material having high efficiency of light emission. Moreover, examples of the material of the emission layer 3 include a metal oxinoid compound [8-hydroxyquinoline metal complex], a naphthalene derivative, an anthracene derivative, a diphenylethylene derivative, a vinyl acetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styrylamine derivative, a bisstyrylbenzene derivative, a trisstyrilbenzene derivative, a perylene derivative, a perynone derivative, an aminopyrene derivative, a pyridine derivative, a rhodamine derivative, an acridine derivative, phenoxazone, quinacridone derivative, rubrene, poly-p-phenylenevinylene, and polysilane.

The electron transport layer 4 has the function of moving electrons to the emission layer 3 efficiently. Here, an example of the material of the electron transport layer 4 is organic compounds, including an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has the function of bringing the energy levels of the second electrode 34 and organic EL layer 33 close to each other to improve the efficiency of electron injection from the second electrode 34 into the organic EL layer 33. This function can lower voltage for driving the organic EL element 35. It is noted that the electron injection layer 5 is also called a cathode buffer layer. Here, examples of the material of the electron injection layer 5 include inorganic alkali compounds, such as lithium fluoride (LiF), magnesium fluoride (MgF₂), calcium fluoride (CaF₂), strontium fluoride (SrF₂), and barium fluoride (BaF₂), as well as aluminum oxide (Al₂O₃) and strontium oxide (SrO).

The second electrode 34 is provided so as to cover the individual organic EL layers 33 and the edge cover 32a, as illustrated in FIG. 3. Further, the second electrode 34 has the function of injecting electrons into the organic EL layers 33. Further, the second electrode 34 is more desirably formed from a material having a small work function in order to improve the efficiency of electron injection into the organic EL layers 33. Here, examples of the material of the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Moreover, the second electrode 34 may be formed from, for instance, alloy of magnesium (Mg) and copper (Cu), alloy of magnesium (Mg) and silver (Ag), alloy of sodium (Na) and potassium (K), alloy of astatine (At) and astatine oxide (AtO₂), alloy of lithium (Li) and aluminum (Al), alloy of lithium (Li), calcium (Ca) and aluminum (Al), or alloy of lithium fluoride (LiF), calcium (Ca) and aluminum (Al). Further, the second electrode 34 may be formed from a conductive oxide, such as tin oxide (SnO), zinc oxide (ZnO), indium tin oxide (ITO), and indium zinc oxide (IZO). Further, the second electrode 34 may be formed by stacking multiple layers formed from the above materials. It is noted that examples of the material having a small work function include magnesium (Mg), lithium (Li), lithium fluoride (LiF), magnesium (Mg)-copper (Cu), magnesium (Mg)-silver (Ag), sodium (Na)-potassium (K), lithium (Li)-aluminum (Al), lithium (Li)-calcium (Ca)-aluminum (Al), and lithium fluoride (LiF)-calcium (Ca)-aluminum (Al).

As illustrated in FIGS. 3 and 7, the sealing film 45 is provided so as to cover the second electrode 34, and the sealing film 45 includes a first inorganic sealing film 41, an organic sealing film 42, and a second inorganic sealing film 43 sequentially stacked on the second electrode 34. The sealing film 45 has the function of protecting the organic EL layers 33 of the organic EL elements 35 from moisture, oxygen, and other things. Here, the first inorganic sealing film 41 and the second inorganic sealing film 43 are each formed from an inorganic insulating film, such as a silicon nitride film, a silicon oxide film, or a silicon oxynitride film. Further, the organic sealing film 42 is formed from an organic resin material, such as acrylic resin, epoxy resin, silicone resin, polyurea resin, parylene resin, polyimide resin, and polyamide resin.

As illustrated in FIG. 7, the organic EL display device 50 also includes, in the frame region F, a plurality of peripheral photo-spacers 32b provided in the form of islands on the flattening film 19 with a conductive layer 31b interposed therebetween, so as to protrude upward in the drawing. Here, the individual peripheral photo-spacers 32b are formed in the same layer and containing the same material as the edge cover 32a. Further, the conductive layer 31b is formed in the same layer and containing the same material as the first electrode 31a.

The organic EL display device 50 also includes, in the frame region F, a first dam wall provided in the form of a frame so as to surround the display region D, and a second dam wall provided in the form of a frame around the first dam wall. Here, each of the first dam wall and second dam wall includes, for instance, a lower resin layer formed in the same layer and containing the same material as the flattening film 19, and an upper resin layer provided on the lower resin layer and formed in the same layer using the same material as the edge cover 32a. It is noted that the first dam wall is provided so as to overlap the outer periphery end of the organic sealing film 42 of the sealing film 45 and is configured to prevent the spread of an ink that is to be the organic sealing film 42.

The foregoing organic EL display device 50 is configured to display an image through the following process in each subpixel P: a gate signal is input to the selection TFT 9a via the gate line 15g to turn on the selection TFT 9a; a data signal is written into the first gate electrode 15b of the drive TFT 9b and the capacitor 9c via the source line 17h; and a current coming from the power supply line 17g and corresponding to the gate voltage of the drive TFT 9b is supplied, so that the emission layer 3 of the organic EL layer 33 emits light. It is noted that in the organic EL display device 50, the emission layer 3 continues to emit light until a gate signal in the next frame is input, because the capacitor 9c retains the gate voltage of the drive TFT 9b even when the selection TFT 9a is turned off.

Next, a method for manufacturing the organic EL display device 50 according to this embodiment will be described. Here, the method for manufacturing the organic EL display device 50 according to this embodiment includes a step of forming a TFT layer, a step of forming an organic EL element layer, and a step of forming a sealing film.

### Step of Forming TFT Layer

The first process step is sequentially forming an aluminum film (about 350 nm thick) and a molybdenum nitride film (about 50 nm thick) onto the glass substrate 10 through, for instance, sputtering to form a first metal film, followed by patterning the first metal film to form the conductive layer 11a, the protective pattern 11p, and other components.

The next is forming a silicon oxide film (about 375 nm thick) onto the substrate surface including the conductive layer 11a and other components through, for instance, plasma chemical vapor deposition (CVD) to form the base coat film 12.

The next is forming a semiconductor film formed from an oxide semiconductor, such as an InGaZnO₄ film (about 30 to 100 nm thick), onto the substrate surface including the base coat film 12 through, for instance, sputtering, followed by patterning the semiconductor film to form the first semiconductor layers 13a and 13b, the second semiconductor layer 13c, and other components.

The next is forming a silicon oxide film (about 150 nm thick) onto the substrate surface including the first semiconductor layer 13a and other components through, for instance, plasma CVD, followed by sequentially forming an aluminum film (about 350 nm thick), a molybdenum nitride film (about 50 nm thick), and other components through sputtering to form a second metal film, followed by patterning the second metal film to form the gate lines 15g, the first gate electrodes 15a and 15b, the second gate electrodes 15c, and other components.

The next is etching the silicon oxide film exposed from the first gate electrodes 15a and 15b, second gate electrodes 15c, and other components to form the gate insulating films 14a, 14b and 14c, and other components.

The next is sequentially forming a silicon oxide film (about 300 nm thick) and a silicon nitride film (about 100 nm thick) onto the substrate surface including the gate insulating film 14a and other components through, for instance, plasma CVD to form the interlayer insulating film 16. It is noted that a part of the first semiconductor layers 13a and 13b and a part of the second semiconductor layer 13c are turned into conductors through heating after the formation of the interlayer insulating film 16, so that the first source region 13aa, the first drain region 13ab, and the first channel region 13ac are formed in the first semiconductor layer 13a, that the first source region 13ba, the first drain region 13bb, and the first channel region 13bc are formed in the first semiconductor layer 13b, and that the second source region 13ca, the second drain region 13cb, and the second channel region 13cc are formed in the second semiconductor layer 13c.

The next is patterning, as appropriate, the interlayer insulating film 16 onto the substrate surface including the interlayer insulating film 16 to form the first contact hole Ha, the second contact hole Hb, the third contact hole Hc, the fourth contact hole Hd, the fifth contact hole He, and the sixth contact hole Hf.

The next is sequentially forming a titanium film (about 30 nm thick), an aluminum film (about 300 nm thick), a titanium film (about 50 nm thick), and other components onto the substrate surface including the contact holes Ha to Hf through, for instance, sputtering to form a third metal film, followed by patterning the third metal film to form the source lines 17h, the power supply lines 17g, the first source electrodes 17a and 17c, the first drain electrodes 17b and 17d, the second source electrodes 17e, the second drain electrodes 17f, and other components.

The next is forming a silicon oxide film (about 250 nm thick) onto the substrate surface including the source lines 17h and other components through, for instance, plasma CVD to form the insulating protective film 18.

The next is applying a photosensitive acrylic resin film (about 2 μm thick) onto the substrate surface including the insulating protective film 18 through, for instance, spin coating or slit coating, followed by subjecting the applied film to pre-baking, exposure, development, and post-baking to form the flattening film 19 having contact holes.

The final process step is removing the insulating protective film 18 exposed from the contact holes of the flattening film 19 to cause the contact holes to reach the first drain electrodes 17d of the drive TFTs 9b.

The TFT layer 20 can be formed through the foregoing process steps.

### Step of Forming Organic EL Element Layer

The organic EL element layer 40 is formed by forming, through a well-known method, the first electrodes 31a, the edge cover 32a, the organic EL layers 33 (the hole injection layer 1, the hole transport layer 2, the emission layer 3, the electron transport layer 4, and the electron injection layer 5), and the second electrode 34 onto the flattening film 19 of the TFT layer 20 formed in the step of forming the TFT layer.

### Step of Forming Sealing Film

The first process step is forming an inorganic insulating film, such as a silicon nitride film, a silicon oxide film, or a silicon oxynitride film, onto the substrate surface including the organic EL element layer 40 formed in the step of forming the organic EL element layer, through plasma CVD using a mask to form the first inorganic sealing film 41.

The next is forming a film of organic resin material, such as acrylic resin, onto the substrate surface including the first inorganic sealing film 41 through, for instance, ink-jet printing to form the organic sealing film 42.

The next is forming an inorganic insulating film, such as a silicon nitride film, a silicon oxide film, or a silicon oxynitride film, onto the substrate including the organic sealing film 42 through plasma CVD using a mask to form the second inorganic sealing film 43 to form the sealing film 45.

The organic EL display device 50 according to this embodiment can be manufactured through the foregoing process steps.

As described above, the organic EL display device 50 according to this embodiment is structured in the following manner: in the peripheral TFTs 9d, which are arranged as the gate driving circuits M of peripheral circuits in the frame region F, the protective pattern 11p formed in the same layer and containing the same material as the conductive layer 11a is provided annularly around the second semiconductor layer 13c, which is formed from an oxide semiconductor, so as to surround the second semiconductor layer 13c in plan view. Accordingly, static electricity accumulated during the manufacturing process steps is more likely to be discharged to the protective pattern 11p, which is provided as a lightning rod, and is less likely to be discharged to the second semiconductor layer 13c, which is surrounded by the protective pattern 11p, so that the peripheral TFTs 9d can be prevented from property degradation resulting from electrostatic discharge. In addition, the protective pattern 11p physically blocks moisture within the flattening film 19 and other components, as well as moisture from the panel outside, thus preventing moisture intrusion into the second semiconductor layer 13c, which is surrounded by the protective pattern 11p, so that the peripheral TFTs 9d can be prevented from property degradation resulting from moisture intrusion. Consequently, the organic EL display device 50, which is provided with the selection TFTs 9a, drive TFTs 9b, and peripheral TFTs 9d all containing oxide semiconductors, can prevent the property degradation of the peripheral TFTs 9d, which constitutes the gate driving circuits M.

The organic EL display device 50 according to this embodiment is also structured such that the drive TFT 9b disposed in each subpixel P of the display region D is provided with the conductive layer 11a adjacently to the glass substrate 10 with respect to the first semiconductor layer 13b. Accordingly, the conductive layer 11a can prevent reach of impurity ions contained in a side adjacent to the glass substrate 10 with respect to the first semiconductor layer 13b, into the first channel region 13bc, and when having a light blocking capability, the conductive layer 11a can prevent light from entering the first channel region 13bc of the first semiconductor layer 13b.

### Other Embodiments

Although the foregoing embodiment has described an organic EL display device as a display device by way of example, the disclosure is applicable to liquid crystal displays and other kinds of display devices.

Although the foregoing embodiment has described, by way of example, an organic EL layer of five-ply stacked structure composed of a hole injection layer, a hole transport layer, an emission layer, an electron transport layer, and an electron injection layer, the organic EL layer may be of, for instance, three-ply stacked structure composed of a hole injection-and-transport layer, an emission layer, and an electron transport-and-injection layer.

Further, although the foregoing embodiment has described, by way of example, an organic EL display device having a first electrode as an anode, and a second electrode as a cathode, the disclosure is also applicable to an organic EL display device with the stacked structure of its organic EL layer being inverted: the first electrode as a cathode, and the second electrode as an anode.

Further, although the foregoing embodiment has described, by way of example, an organic EL display device in which a TFT's electrode connected to the first electrode constitutes a drain electrode, the disclosure is also applicable to an organic EL display device in which the TFT's electrode connected to the first electrode constitutes a source electrode.

Further, although the foregoing embodiment has described an organic EL display device as a display device by way of example, the disclosure is applicable to a display device provided with a plurality of light-emitting elements that are driven by current; for instance, the disclosure is applicable to a display device provided with quantum-dot light-emitting diodes (QLEDs), which are light-emitting elements including a quantum-dot-containing layer.

### Industrial Applicability

As described above, the disclosure is useful for display devices for use in large-scale television receivers.

1. A display device comprising:
a base substrate; and
a thin-film transistor layer provided on the base substrate, the thin-film transistor layer including a plurality of first thin-film transistors arranged for each of a plurality of subpixels constituting a display region, and including a plurality of second thin-film transistors arranged as peripheral circuits in a frame region around the display region,
each of the plurality of first thin-film transistors and each of the plurality of second thin-film transistors including a first semiconductor layer and a second semiconductor layer, respectively, both formed from an oxide semiconductor,
the thin-film transistor layer including, in at least one of the plurality of first thin-film transistors, a conductive layer provided adjacently to the base substrate with respect to the first semiconductor layer,
wherein a protective pattern formed in a same layer and containing a same material as the conductive layer is provided around the second semiconductor layer in a plan view.

2. The display device according to claim 1, wherein the protective pattern is provided annularly so as to surround the second semiconductor layer.

3. The display device according to claim 2, wherein the protective pattern is provided such that a portion overlapping a wiring line coupling to an electrode of each of the plurality of second thin-film transistors is narrower than a portion not overlapping the wiring line.

4. The display device according to claim 1, wherein the protective pattern is provided in a form of a plurality of islands so as to surround the second semiconductor layer, and not to overlap a wiring line coupling to an electrode of each of the plurality of second thin-film transistors.

5. The display device according to claim 1, wherein
the thin-film transistor layer includes a stack of, in sequence, a first metal film, a first inorganic insulating film, a semiconductor film formed from the oxide semiconductor, a second inorganic insulating film, a second metal film, a third inorganic insulating film, a third metal film, a fourth inorganic insulating film, and a flattening film formed from an organic resin material,
the first semiconductor layer and the second semiconductor layer are formed from the semiconductor film, and
the conductive layer and the protective pattern are formed from the first metal film.

6. The display device according to claim 1, wherein the at least one of the plurality of first thin-film transistors provided with the conductive layer is a drive thin-film transistor.

7. The display device according to claim 1, comprising:
a light-emitting element layer provided on the thin-film transistor layer, and including a plurality of light-emitting elements arranged in correspondence with the plurality of subpixels constituting the display region; and
a sealing film provided on the light-emitting element layer.

8. The display device according to claim 7, wherein each of the plurality of light-emitting elements is an organic electroluminescence element.
